(19) United States
(12) Patent Application Publication
(10) Pub. No.: US 2025/0142809 A1
(43) Pub. Date: May 1, 2025

(54) SEMICONDUCTOR DEVICES

(71) Applicant: Samsung Electronics Co., Ltd., Suwon-si (KR)

(72) Inventors: Kangin Kim, Suwon-si (KR); Kyounghwan Kim, Suwon-si (KR)

(21) Appl. No.: 18/760,232

(22) Filed: Jul. 1, 2024

(30) Foreign Application Priority Data
Oct. 26, 2023 (KR) 10-2023-0144994

(51) Int. Cl. H10B 12/00

(52) U.S. Cl. CPC H10B 12/34; H10B 12/053; H10B 12/315

(57) ABSTRACT

A semiconductor device includes a gate trench extending in a first direction on a substrate, first active fins protruding from a bottom of the gate trench, an upper surface of each of the first active fins having a first vertical level, a second active fin in the gate trench, an upper surface of the second active fin having a second vertical level higher than the first vertical level, and a gate structure on an isolation pattern filling the gate trench. A first portion of the gate structure overlapping with upper portions of the first active fins includes a first electrode. A second portion of the gate structure overlapping an upper portion of the second active fin includes a second electrode. A vertical height of the second electrode is greater than a vertical height of the first electrode.

### CROSS-REFERENCE TO RELATED APPLICATION

This application claims priority under 35 USC § 119 to Korean Patent Application No. 10-2023-0144994, filed on Oct. 26, 2023, in the Korean Intellectual Property Office (KIPO), the content of which is incorporated by reference herein in its entirety.

### BACKGROUND

### 1. Field

Example embodiments relate to a semiconductor device. Particularly, example embodiments relate to a semiconductor device including a gate structure.

### 2. Description of the Related Art

A semiconductor device may include agate structure disposed on active fins. The gate structure may include an electrode including a metal. Due to an influence of the active fins disposed below the gate structure, a defect in which the gate structure is broken may occur.

### SUMMARY

Example embodiments provide a semiconductor device including a gate structure. According to example embodiments, there is provided a semiconductor device. The semiconductor device may include a gate trench at an upper portion of a substrate, the gate trench extending in a first direction; first active fins being spaced apart from each other in the gate trench, each of the first active fins protruding from a bottom of the gate trench, and an upper surface of each of the first active fins having a first vertical level; a second active fin in the gate trench, the second active fin protruding from the bottom of the gate trench, and an upper surface of the second active fin having a second vertical level higher than the first vertical level, wherein a distance from the second active fin to an end of the gate trench in the first direction is smaller than a distance from the first active fins to the end of the gate trench in the first direction; an isolation pattern filling a lower portion of the gate trench to expose upper sidewalls and top surfaces of the first active fins and the second active fin; and a gate structure on the isolation pattern in the gate trench, the gate structure filling the gate trench, wherein a first portion of the gate structure overlapping with upper portions of the first active fins has a first stacked structure including a gate insulation layer, a first electrode, and a first capping layer pattern, wherein a second portion of the gate structure overlapping an upper portion of the second active fin has a second stacked structure including the gate insulation layer, a second electrode, and a second capping layer pattern, and wherein a vertical height of the second electrode is greater than a vertical height of the first electrode.

According to example embodiments, there is provided a semiconductor device. The semiconductor device may include a substrate including a cell array region and an interface region adjacent to an edge of the cell array region; first active patterns on the substrate of the cell array region and a first isolation pattern in a first trench between adjacent first active patterns; a second isolation pattern on the interface region of the substrate, the second isolation pattern disposed in a second trench having an inner width greater than an inner width of the first trench; a gate trench passing through upper portions of the first active pattern, the first isolation pattern, and the second isolation pattern, the gate trench extending in a first direction from the cell array region to the interface region; first active fins spaced apart from each other in the gate trench on the cell array region, each of the first active fins including a portion protruding from the first isolation pattern, and the portion protruding from the first isolation pattern having a first vertical height; a second active fin in the gate trench, the second active fin protruding from the first isolation pattern and the second isolation pattern, wherein a portion of the second active fin protruding from the first isolation pattern and the second isolation pattern has a second vertical height greater than the first vertical height, and wherein a distance from the second active fin to an end of the gate trench in the first direction is smaller than a distance from the first active fins to the end of the gate trench in the first direction; and a gate structure on the first isolation pattern and the second isolation pattern within the gate trench and filling the gate trench, wherein a first portion of the gate structure overlapping with upper portions of the first active fins has a first stacked structure including a gate insulation layer, a first electrode, and a first capping layer pattern, wherein a second portion of the gate structure overlapping an upper portion of the second active fin has a second stacked structure including the gate insulation layer, a second electrode, and a second capping layer pattern, and wherein a vertical height of the second electrode is greater than a vertical height of the first electrode. According to example embodiments, there is provided a semiconductor device. The semiconductor device may include first active fins protruding from a substrate, a top surface of each of the first active fins being at a first vertical level; a second active fin protruding from the substrate, a top surface of the second active fin being at a second vertical level higher than the first vertical level; a first gate structure extending in a first direction on the first active fins, the first gate structure having a first stacked structure including a gate insulation layer, a first electrode, and a first capping layer pattern; and a second gate structure on the second active fin, the second gate structure contacting an end of the first gate structure in the first direction, the second gate structure having a second stacked structure including the gate insulation layer, a second electrode, and a second capping layer pattern, wherein a lowermost surface of the first electrode is coplanar with a lowermost surface of the second electrode, and an upper surface of the second electrode is higher than an upper surface of the first electrode.

In a semiconductor device according to example embodiments, the vertical height of the second electrode included in the second portion of the gate structure overlapping the second active fin is greater than the vertical height of the first electrode included in the first portion of the gate structure overlapping the first active fins. As the second electrode has a sufficient height, defects in which the second electrode is broken during processes for manufacturing of the semiconductor device may be decreased.

### BRIEF DESCRIPTION OF THE DRAWINGS

Various example embodiments will be more clearly understood from the following detailed description taken in conjunction with the accompanying drawings. FIGS. 1 to 26 represent various non-limiting, example embodiments as described herein.

FIG. 1 is a plan view illustrating a semiconductor device according to example embodiments;

FIG. 2 is a plan view illustrating a portion of a semiconductor device according to example embodiments;

FIG. 3 is a cross-sectional view illustrating a semiconductor device according to example embodiments;

FIG. 4 is an enlarged plan view of a gate structure in a semiconductor device according to example embodiments;

FIG. 5 is a cross-sectional view illustrating a semiconductor device according to some example embodiments;

FIG. 6 is an enlarged plan view of a gate structure in a semiconductor device according to some example embodiments;

FIG. 7 is a cross-sectional view illustrating a semiconductor device according to example embodiments;

FIG. 8 is a cross-sectional view illustrating a semiconductor device according to example embodiments; and

FIGS. 9 to 26 are cross-sectional views and plan views for illustrating a method of manufacturing a semiconductor device according to example embodiments.

### DETAILED DESCRIPTION

Hereinafter, various example embodiments will be described in detail with reference to the accompanying drawings.

In the detailed description, two directions parallel to an upper surface of a substrate and perpendicular to each other are defined as a first direction D1 and a second direction D2, respectively. A direction having an acute angle with each of the directions D1 and D2 is defined as a third direction D3. A direction perpendicular to the upper surface of the substrate is defined as a vertical direction.

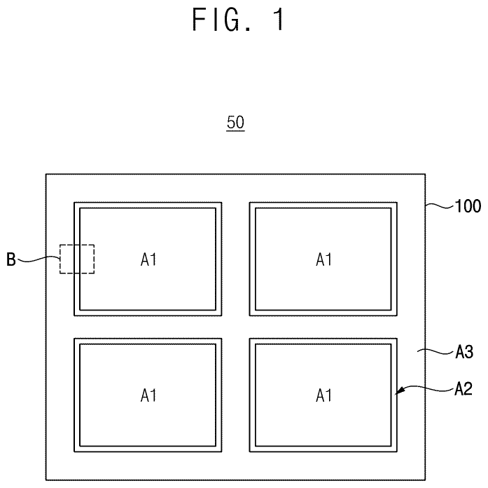

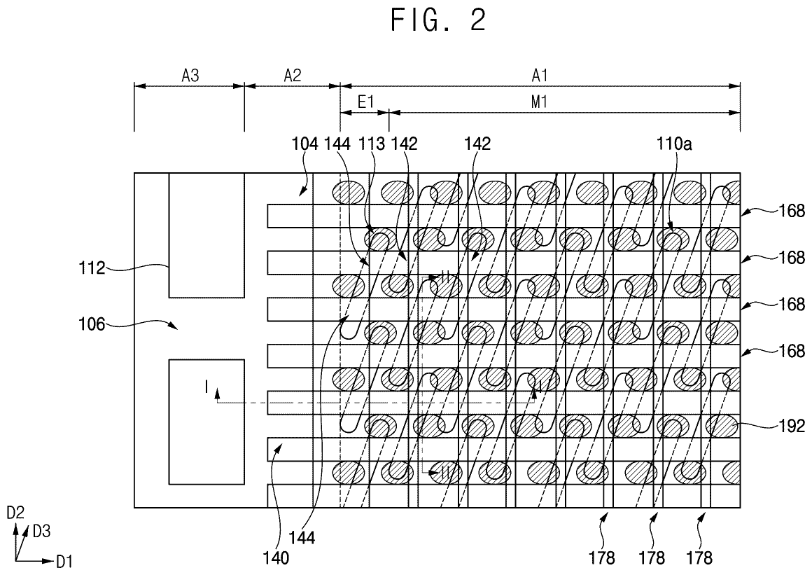

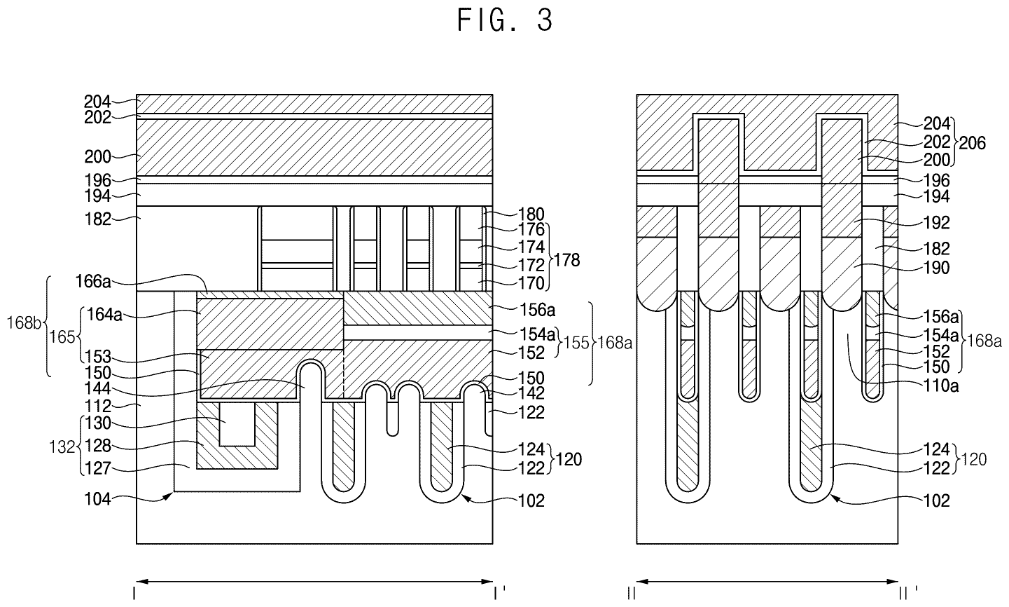

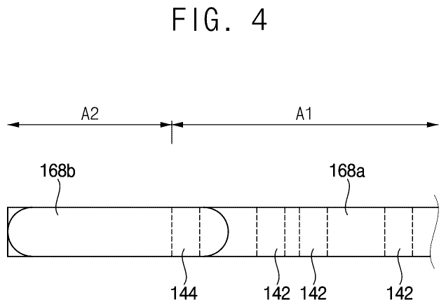

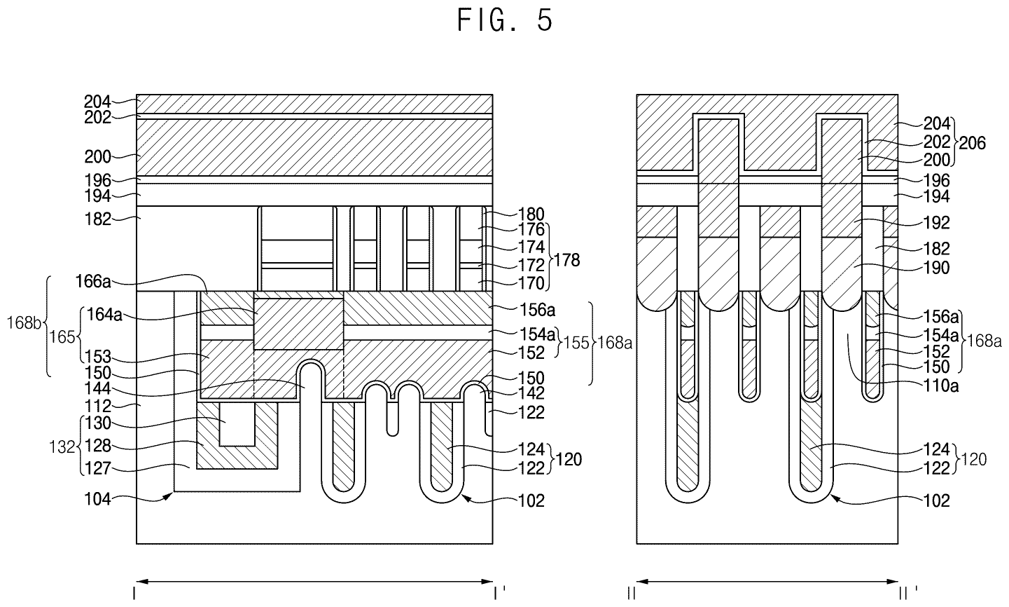

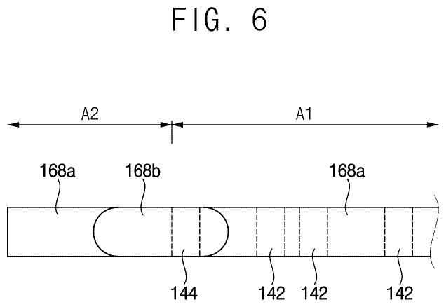

FIG. 1 is a plan view illustrating a semiconductor device according to example embodiments. FIG. 2 is a plan view illustrating a portion of a semiconductor device according to example embodiments. FIG. 3 is a cross-sectional view illustrating a semiconductor device according to example embodiments. FIG. 4 is an enlarged plan view of a gate structure in a semiconductor device according to example embodiments. FIG. 5 is a cross-sectional view illustrating a semiconductor device according to some example embodiments. FIG. 6 is an enlarged plan view of a gate structure in a semiconductor device according to some example embodiments.

FIG. 2 is an enlarged plan view of a portion B of FIG. 1. FIGS. 4 and 6 illustrate portions of one gate structure. In each of FIGS. 3 and 5, a left cross-section is a cross section cut along line I-I′ of FIG. 2, and a right cross-section is a cross section cut along line II-II′ of FIG. 2.

Referring to FIGS. 1 to 4, a semiconductor device 50 may include a substrate 100 including a cell array region A1, a peripheral circuit region A3, and an interface region A2. The semiconductor device may be a DRAM device. The cell array region A1 may be a memory cell region, and the peripheral circuit region A3 may be a region for forming core circuits or peripheral circuits. For example, the cell array region A1 may include memory cells composed of cell transistors and capacitors, and the peripheral circuit region A3 may include peripheral circuit transistors (not shown) for delivering electrical signals and/or power to the memory cells. In example embodiments, the peripheral circuit transistors may form various circuits such as a command decoder, control logic, address buffer, row decoder, column decoder, sense amplifier, and data input/output circuit, etc.

The interface region A2 may be positioned between the cell array region A1 and the peripheral circuit region A3.

The substrate 100 may be formed of or include silicon, e.g., single crystal silicon. In some example embodiments, the substrate 100 may include at least one selected from Ge, SiGe, SiC, GaAs, InAs, and InP.

A first trench 102 may be formed on the cell array region A1 of the substrate 100, and a first isolation pattern 120 may fill the first trench 102. A protruding portion of the substrate 100 between the first trenches 102 may be referred to as a first active pattern 110a. An upper portion of the first active pattern 110a exposed by the first isolation pattern 120 may be referred to as a first active region.

An active pattern positioned last in the first direction D1 on the cell array region A1 (e.g., at a position closest to the interface region A2) may be referred to as a second active pattern 113.

An edge region within the cell array region A1 may be referred to as a cell block edge region E1. The cell block edge region E1 may correspond to the edge region of the cell array region A1 including the second active pattern 113. The cell block edge region E1 may be adjacent to the interface region A2, and may contact the interface region A2. The cell array region A1 excluding the cell block edge region E1 may be referred to as a main cell region M1.

A second trench 104 may be formed on the interface region A2 of the substrate 100, and a second isolation pattern 132 may fill the second trench 104. The second trench 104 may surround an edge of the cell array region A1.

A third trench 106 may be formed in the peripheral circuit region A3 of the substrate 100. A third isolation pattern (not shown) may fill the third trench 106. A protruding portion of the substrate 100 between the third trenches 106 may be referred to as a peripheral active pattern 112. An upper portion of the peripheral active pattern 112 exposed by the third isolation pattern may be a second active region.

The first active pattern 110a may be arranged so that the third direction D3 may be a longitudinal direction. For example, the first active patterns 110a may extend in the third direction D3 that is different from, but coplanar with, the first and second directions D2. A plurality of the first active patterns 110a may be regularly arranged to be spaced apart from each other in each of the first and second directions D1 and D2. Depending on an arrangement of the first active patterns 110a, an inner width of the first trench 102 between the first active patterns 110a may be changed. Since the first active patterns 110a are densely arranged, the inner width of the first trench 102 may be less than an inner width of each of the second and third trenches 106.

A stacked structure of the first isolation pattern 120 may be changed depending on the inner width of the first trench 102. In example embodiments, a first portion of the first isolation pattern 120 filling a portion having a narrowest first width within the first trench 102 may include only the first insulation layer 122. In example embodiments, a second portion of the first isolation pattern 120 filling a remaining portion wider than the first width within the first trench 102 may include the first insulation layer 122 and a second insulation layer 124. For example, the first insulation layer 122 may be conformally disposed on the surface of the first trench 102 and the second insulation layer 124 may be conformally disposed on the surface of the first insulation layer 122. The first insulation layer 122 may be formed of or include, e.g., silicon oxide, and the second insulation layer 124 may be formed of or include, e.g., silicon nitride.

In example embodiments, the second isolation pattern 132 may include a buried insulation layer 127, an insulation liner layer 128, and a gap filling insulation layer 130.

The buried insulation layer 127 may be conformally disposed on a surface of the second trench 104. In example embodiments, the buried insulation layer 127 may be formed of or include silicon oxide.

The insulation liner layer 128 may be conformally disposed on the buried insulation layer 127 along a surface profile of the second trench 104. In example embodiments, the insulation liner layer 128 may be formed of or include silicon nitride.

The gap filling insulation layer 130 may be disposed on the insulation liner layer 128 to fill the second trench 104. In example embodiments, the gap filling insulation layer 130 may be formed of or include silicon oxide such as TOSZ (tonen silazene), USG (undoped silicate glass), BPSG (boro-phospho-silicate glass), PSG (phosphosilicate glass), FOX (flowable oxide), and PE-TEOS (plasma enhanced deposition of tetraethyl-ortho-silicate), or FSG (fluoride silicate glass).

In example embodiments, the third isolation pattern may have a stacked structure the same as the stacked structure of the second isolation pattern 132 or a stacked structure the same as the stacked structure of a second portion of the first isolation pattern 120, depending on the inner width of the third trench. However, the insulation materials and the stacked structures constituting each of the first to third isolation patterns 120 and 132 may not be limited thereto.

In the cell array region A1, the second active patterns 113 positioned on the cell block edge region E1 may have an arrangement density lower than an arrangement density of the first active patterns 110a positioned on the main cell region M1.

A plurality of gate trenches 140 extending in the first direction D1 may be formed in the cell array region A1 and the interface region A2 of the substrate 100. The gate trench 140 may extend from the cell array region A1 to at least a portion of the interface region A2. The plurality of gate trenches 140 may be spaced apart in the second direction D2. Two gate trenches 140 being spaced apart from each other may be disposed on each of the first active patterns 110a.

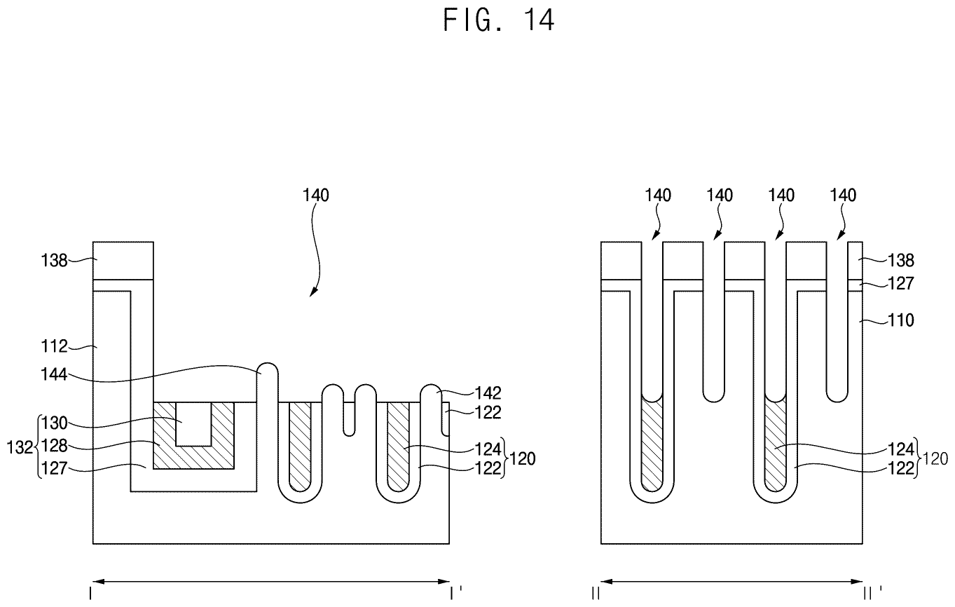

The gate trench 140 may be formed by etching an upper portion of the substrate 100 corresponding to the first and second active patterns 110a and 113 and upper portions of the first isolation pattern 120 and the second isolation pattern 132. Accordingly, the gate trench 140 may pass through the upper portion of the substrate 100 corresponding to the first and second active patterns 110a and 113 and the upper portions of the first isolation pattern 120 and the second isolation pattern 132. The first active pattern 110a, the second active pattern 113, the first isolation pattern 120, and the second isolation pattern 132 may be exposed on a bottom of the gate trench 140 (referred to FIG. 14). The first and second isolation patterns 120 and 132 may be positioned below the gate trench 140.

In the cell array region A1, a vertical level of an upper surface (e.g., a vertical level of a top surface) of each of the first and second active patterns 110a and 113 exposed by a bottom of the gate trench 140 may be lower than a vertical level of an upper surface of each of the first and second active patterns 110a and 113 between the gate trenches 140. A vertical level of an upper surface of the first and second isolation patterns 120 and 132 exposed by the bottom of the gate trench 140 may be lower than a vertical level of an upper surface of the first and second isolation patterns 120 and 132 between the gate trenches 140.

In the cell array region A1, the vertical level of the upper surface of the first and second active patterns 110a and 113 exposed by the bottom of the gate trench 140 and the vertical level of the upper surface of the first isolation pattern 120 may be different from each other.

In the main cell region M1, the vertical level of the upper surface of the first active pattern 110a exposed by the bottom of the gate trench 140 may be higher than the vertical level of the upper surface of the first isolation pattern 120 exposed by the bottom of the gate trench 140. The first active pattern 110a within the gate trench 140 may be referred to as a first active fin 142.

As used herein, the term “vertical level” of a surface refers to a level of the surface above a bottom surface of the substrate 100 in the vertical direction.

The first active fin 142 may protrude from a lowermost surface of the gate trench 140. A portion of the first active fin 142 protruding from the first isolation pattern 120 may have a first vertical height. The portion of the first active fin 142 that has the first vertical height may extend from an upper surface of the first isolation pattern 120 to a topmost surface of the first active fin 142. A surface of the first active fin 142 may be exposed within the gate trench 140. The first active fins 110a may be spaced apart from each other within the gate trench 140.

As used herein, the terms “height” and vertical height” of an element refer to a distance from a bottom of the element to a top of the element in the vertical direction.

The vertical level of the upper surface of the second active pattern 113 exposed by the bottom of the gate trench 140 in the cell block edge region E1 may be higher than the vertical level of the upper surface of each of the first and second isolation patterns 120 and 132 exposed by the bottom of the gate trench 140. The second active pattern 113 may be disposed between the first isolation pattern 120 and the second isolation pattern 132.

In the interface region A2 and the cell block edge region E1, the vertical level of the upper surface of the second active pattern 113 exposed by the bottom of the gate trench 140 may be higher than the vertical level of the upper surface of the first and second isolation patterns 120 and 132 exposed by the bottom of the gate trench 140. The second active pattern 113 in the gate trench 140 may be referred to as a second active fin 144. A surface of the second active fin 144 may be exposed within the gate trench 140. The second active fin 144 may be positioned closest to an end of the gate trench 140 in the first direction D1 within the gate trench 140. For example, a distance from the end of the gate trench 140 to the second active fin 144 may be less than a distance from the end of the gate trench 140 to the first active fins 142.

A separation distance from the second active fin 144 to the end of the gate trench 140 in the first direction D1 may be greater than each of a separation distance between the first active fins 142 and a separation distance between the first active fin 142 and the second active fin 144. The second active fins 144 may have an arrangement density lower than an arrangement density of the first active fins 142.

The second isolation pattern 132 may be formed between the second active fin 144 and the end of the gate trench 140 in the first direction D1. The first isolation pattern 120 may be formed between the first active fins 142 and between the first active fin 142 and the second active fin 144. A stacked structure of the second isolation pattern 132 may be different from the stacked structure of the first isolation pattern 120.

A portion of the second active fin 144 protruding from the first and second isolation patterns 120 and 132 may have a second vertical height greater than the first vertical height. The portion of the second active fin 144 having the second vertical height may extend from an upper surface of the first and second isolation patterns 120 and 132 to a topmost surface of the second active fin 144. A vertical level of a top surface (e.g., a topmost surface) of the second active fin 144 may be higher than the vertical level of a top surface (e.g., a topmost surface) of the first active fin 142.

A gate structure 168 may be formed in the gate trench 140. The gate structure 168 may serve as a word line structure.

The gate structure 168 may include a first portion 168a disposed on the main cell region M1 of the cell array region A1 and a second portion 168b disposed on of the cell block edge region E1 of the cell array region A1 and on the interface region A2.

The first portion 168a of the gate structure may overlap upper portions of the first active fins 142. The second portion 168b of the gate structure may overlap an upper portion of the second active fin 144.

The first portion 168a and the second portion 168b of the gate structure may have different stacked structures to each other. In the gate structure 168, a portion excluding the second portion 168b may be the first portion 168a.

In example embodiments, the first portion 168a of the gate structure may include a gate insulation layer 150, a first electrode 155, and a first capping layer pattern 156a stacked. In example embodiments, the second portion 168b of the gate structure may include the gate insulation layer 150, a second electrode 165, and a second capping layer pattern 166a stacked.

The gate insulation layer 150 may be formed conformally on sidewalls and bottom of the gate trench 140. The gate insulation layer 150 may be formed of or include, e.g., silicon oxide.

The first electrode 155 and the second electrode 165 may laterally contact each other, and may extend in the first direction D1. The first electrode 155 and the second electrode 165 may be electrically connected to each other, so that the first electrode 155 and the second electrode 165 may serve as one word line.

A third vertical height, which is a height from a lowermost surface of the first electrode 155 to an upper surface of the first electrode 155, may be less than a fourth vertical height, which is a height from a lowermost surface of the second electrode 165 to an upper surface of the second electrode 165. A vertical level of the upper surface of the first electrode may be lower than a vertical level of the upper surface of the second electrode 165.

The upper surface of the first electrode 155 may be substantially flat. The upper surface of the second electrode 165 may be substantially flat. A step difference between the upper surfaces of the first electrode 155 and the second electrode 165 may be at an interface of the first and second electrodes 155 and 165.

The first and second electrodes 155 and 165 may be formed of or include at least one same metal material. In example embodiments, a lowermost metal material included in the first and second electrodes 155 and 165 may be the same.

The first electrode 155 may have a structure in which one or two or more conductive materials are stacked. The second electrode 165 may have a structure in which at least two layers of conductive patterns are stacked. The second electrode 165 may be formed of or include a metal or a metal nitride. For example, the second electrode 165 may not include polysilicon.

In example embodiments, the first electrode 155 may include a first conductive pattern 152 and a second conductive pattern 154a stacked. The first conductive pattern 152 may be formed of or include the metal, e.g., Ti, TiN, Ta, TaN, W, WN, TiSiN, WSiN, etc. In the first conductive pattern 152, the metal may be used alone, or two or more metals may be a stacked. For example, the first conductive pattern 152 may include titanium nitride. The second conductive pattern 154a may be formed of or include polysilicon.

In example embodiments, the second electrode 165 may include a third conductive pattern 153 and a fourth conductive pattern 164a stacked.

The first conductive patterns 152 included in the first electrode 155 and the third conductive patterns 153 included in the second electrode 165 may be formed by the same deposition process, and thus the first and third conductive patterns 152 and 153 may include the same metal. In example embodiments, an upper surface of the third conductive pattern 153 may be lower than the upper surface of the first conductive pattern 152. In some example embodiments, the upper surface of the third conductive pattern 153 may be coplanar with the upper surface of the first conductive pattern 152. A vertical level of the upper surface of the third conductive pattern 153 may be higher than the vertical level of a top surface of the second active fin 144.

In example embodiments, a lowermost surface of the first conductive pattern 152 and a lowermost surface of the third conductive pattern 153 may be coplanar with each other.

The fourth conductive pattern 164a may be formed of or include a metal, e.g., TiN, Ta, TaN, W, WN, TiSiN, WSiN, etc. In the fourth conductive pattern 164a, the metal may be used alone, or two or more metals may be a stacked.

In example embodiments, the third conductive pattern 153 and the fourth conductive pattern 164a may include the same metal. For example, the third and fourth conductive patterns may include titanium nitride. In some example embodiments, the third conductive pattern 153 and the fourth conductive pattern 164a may include different metals from each other.

Since the third conductive pattern 153 and the fourth conductive pattern 164a are formed by different stages of deposition processes, an interface between the upper surface of the third conductive pattern 153 and the lower surface of the fourth conductive pattern 164a may be identified.

An upper surface of the fourth conductive pattern 164a may be higher than an upper surface of the second conductive pattern 154a. The upper surface of the fourth conductive pattern 164a may be lower than an upper surface of the peripheral active pattern 112 adjacent to the upper portion of the gate trench 140.

The first capping layer pattern 156a may be formed of or include, e.g., silicon nitride or silicon oxynitride.

The second capping layer pattern 166a may be formed of or include silicon nitride or silicon oxynitride. The first and second capping layer patterns 156a and 166a may be formed by different stages of deposition processes.

Upper surfaces of the first and second capping layer patterns 156a and 166a may be substantially coplanar with each other. A vertical height (e.g., a thickness) of the first capping layer pattern 156a may be greater than a vertical height of the second capping layer pattern 166a.

The first and second portions 168a and 168b of the gate structure may completely fill the gate trench 140. In example embodiments, the upper surfaces of the first and second capping layer patterns 156a and 166a of the gate structure 168 may be coplanar with a top portion of the gate trench 140.

Accordingly, a metal pattern included in the first portion 168a of the gate structure may be the first conductive pattern 152, and a metal pattern included in the second portion 168b of the gate structure may be the third conductive pattern 153 and the fourth conductive pattern 164a. A vertical height (e.g., a thickness) of the metal pattern included in the second portion 168b of the gate structure may be greater than a vertical height of the metal pattern included in the first portion 168a of the gate structure.

If the first and second portions of the gate structure have the same stacked structure, heights of the upper surfaces of the metal patterns in the first and second portions may be the same. Accordingly, the metal pattern on a top surface of the second active fin 144 may not have a sufficient vertical height. In this case, when an operating voltage is applied to the gate structure 168, the metal in the metal pattern may be migrated, and thus metal atoms may be decreased in regions where the vertical height of the metal pattern is low. Therefore, defects in which the metal pattern is broken (or cut) may occur. That is, the metal pattern on the top surface of the second active fin may be disconnected, so that a defect of the gate structure 168 may occur.

However, in example embodiments, as described above, the second portion 168b of the gate structure may have a structure in which the third and fourth conductive patterns 153 and 164a including the metal are stacked, so that the metal pattern having sufficient vertical thickness may be disposed on the second active fin 144. Accordingly, defects in which the metal pattern on the top surface of the second active fin 144 is disconnected may be decreased.

The second portion 168b of the gate structure may overlap the upper portion of the second active fin 144. A first end (e.g., an end contacting the first portion) of the second portion 168b of the gate structure may be disposed between the second active fin 144 and the first active fin 142. A second end opposing the first end of the second portion 168b of the gate structure may be positioned within the gate trench 140 on the interface region A2.

In example embodiments, in the second portion 168b of the gate structure, the fourth conductive pattern 164a and the second capping layer pattern 166a may have a pillar shape.

In example embodiments, as shown in FIGS. 3 and 4, the second end of the second portion 168b of the gate structure may coincide with an end of the gate trench 140 in the first direction. The second portion 168b of the gate structure may extend from a portion overlapping the upper portion of the second active fin 144 to the end of the gate trench 140 in the first direction D1. In this case, the gate structure 168 may be arranged in the order of the second portion 168b and the first portion 168a in the first direction D1 from the end of the gate trench 140 on the interface region A2. That is, the first portion 168a may not be positioned within the gate trench 140 on the interface region A2.

In some example embodiments, as shown in FIGS. 5 and 6, the second end of the second portion 168b of the gate structure may not coincide with the end of the gate trench 140 in the first direction, and may be spaced apart from the end of the gate trench in the first direction 140. For example, the second portion 168b of the gate structure may be disposed at a portion overlapping the upper portion of the second active fin 144. Therefore, the first portion 168a of the gate structure may also be disposed at a region from an end of the second portion 168b of the gate structure to the end of the gate trench 140 in the first direction D1. In this case, the gate structure 168 may be arranged in the order of the first portion 168a, the second portion 168b, and the first portion 168a again in the first direction D1 from the end of the gate trench 140 on the interface region A2. That is, the first portion 168a and the second portion 168b of the gate structure may be disposed within the gate trench 140 on the interface region A2.

A buffer insulation layer (not shown) may be formed on the first active pattern 110a, the first isolation pattern 120, and the first and second capping layer patterns 156a and 166a on the cell array region A1 and the interface region A2. The buffer insulation layer may include openings exposing a central portion of each of the first active patterns 110a in the third direction D3.

A bit line structure 178 may be disposed on the buffer insulation layer on the cell array region A1 and the interface region A2. The bit line structure 178 may contact the first active patterns 110a exposed by the openings. The bit line structure 178 may extend in the second direction D2.

In example embodiments, the bit line structure 178 may include a lower conductive pattern 170, a barrier pattern 172, a first metal pattern 174, and a third capping layer pattern 176 sequentially stacked. The lower conductive pattern 170 may be formed of or include, e.g., doped polysilicon. The barrier pattern 172 may be formed of or include, e.g., TiN or TiSiN. The first metal pattern 174 may be formed of or include, e.g., tungsten.

A spacer 180 may be formed on sidewalls of the bit line structure 178. In example embodiments, a plurality of spacers 180 may be laterally stacked from the sidewalls of the bit line structure 178.

In example embodiments, the bit line structure 178 on the main cell region M1 may have a second width. A last bit line structure 178 in the first direction D1 formed on the cell block edge region E1 and the interface region A2 may have a width greater than the second width.

A fence insulation pattern 182 may be formed on the upper surface of the gate structure 168 in a space between the bit line structures 178. The fence insulation pattern 182 may be formed of or include, e.g., silicon nitride.

A contact hole exposing the first active pattern 110a may be formed between the bit line structures 178 and the fence insulation patterns 182.

A lower contact plug 190 and a landing pad pattern 192 may be formed in the contact hole. The lower contact plug 190 may fill a lower portion of the contact hole. The landing pad pattern 192 may be disposed on the lower contact plug 190. An upper surface of the landing pad pattern 192 may be higher than an upper surface of the bit line structure 178.

The lower contact plug 190 may be formed of or include, e.g., polysilicon doped with impurities. The landing pad pattern 192 may be formed of or include, e.g., a barrier metal pattern and a metal pattern.

A plurality of landing pad patterns 192 may be arranged. Each of the landing pad patterns 192 may have an isolated island shape, in a plan view. An upper insulation pattern 194 may be disposed between the landing pad patterns 192.

In the cell array region A1, a first etch stop layer 196 may be disposed on the landing pad patterns 192 and the upper insulation pattern 194. A capacitor 206 may be disposed on each of the landing pad patterns 192 by passing through the first etch stop layer 196. The capacitor 206 may include a lower electrode 200, a dielectric layer 202, and an upper electrode 204.

In example embodiments, a stacked structure of the conductive patterns included in each of the first electrode 155 and the second electrode 165 may be variously modified.

In the above description, the example embodiments may be described using a DRAM device, but are not limited thereto. The gate structure included in the example embodiments may be used in gate structures of fin field effect transistors in various semiconductor devices.

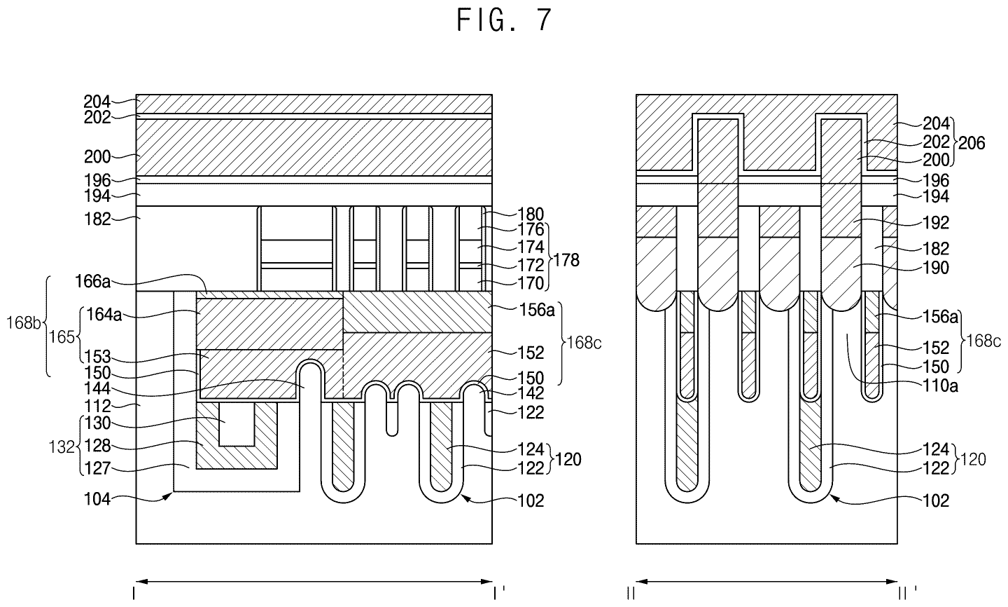

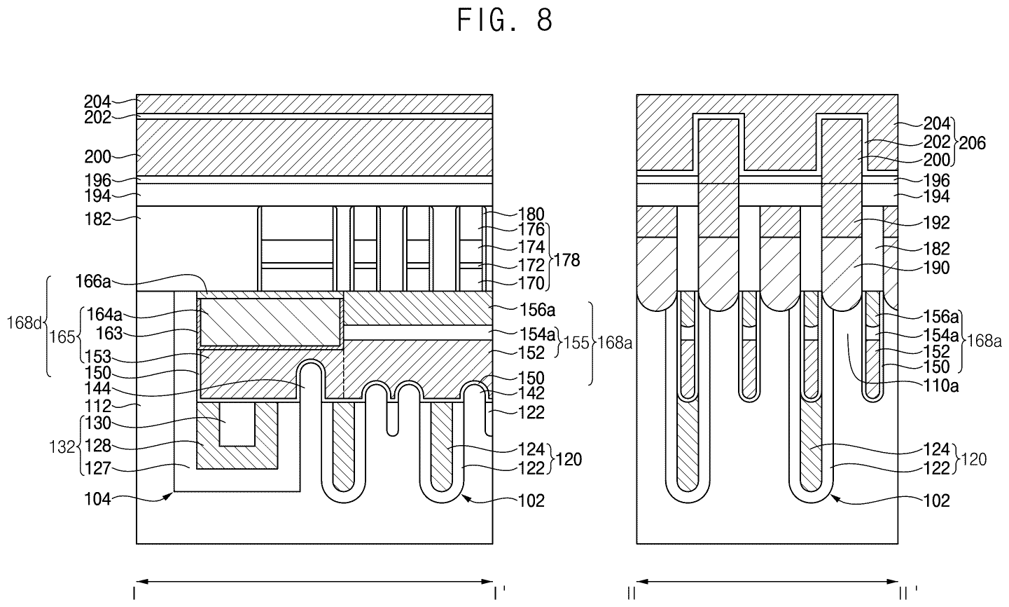

FIG. 7 is a cross-sectional view illustrating a semiconductor device according to example embodiments. FIG. 8 is a cross-sectional view illustrating a semiconductor device according to example embodiments.

The semiconductor device as shown in FIGS. 7 and 8 may be the same as the semiconductor device described with reference to FIG. 3, except for a stacked structure of the conductive patterns included in each of the first and second electrodes.

Referring to FIG. 7, a first electrode may include only the first conductive pattern 152. The second electrode 165 may include the third conductive pattern 153 and the fourth conductive pattern 164a stacked. The first electrode may not include the second conductive pattern including the polysilicon. Accordingly, a first portion 168c of a gate structure may include the gate insulation layer 150, the first conductive pattern 152, and the first capping layer pattern 156a stacked. The second portion 168b of the gate structure may include the gate insulation layer 150, the third conductive pattern 153, the fourth conductive pattern 164a, and the second capping layer pattern 166a stacked. In example embodiments, the second electrode 165 may be substantially the same as the second electrode described with reference to FIG. 3.

Referring to FIG. 8, the first electrode 155 may include the first conductive pattern 152 and the second conductive pattern 154a stacked. In example embodiments, the first electrode 155 may be substantially the same as the first electrode described with reference to FIG. 3.

A second electrode 165 may include the third conductive pattern 153, the barrier pattern 163, and the fourth conductive pattern 164a stacked. The barrier pattern 163 may surround sidewalls and a bottom of the fourth conductive pattern 164a. In example embodiments, the barrier pattern 163 may be formed of or include, e.g., Ti, TiN, Ta, TaN, etc., and the fourth conductive pattern 164a may be formed of or include, e.g., tungsten.

Accordingly, the first portion 168a of the gate structure may include the gate insulation layer 150, the first conductive pattern 152, the second conductive pattern 154a, and the first capping layer pattern 156a stacked. A second portion 168d of the gate structure may include the gate insulation layer 150, the third conductive pattern 153, the barrier pattern 163, the fourth conductive pattern 164a, and the second capping layer pattern 166a stacked.

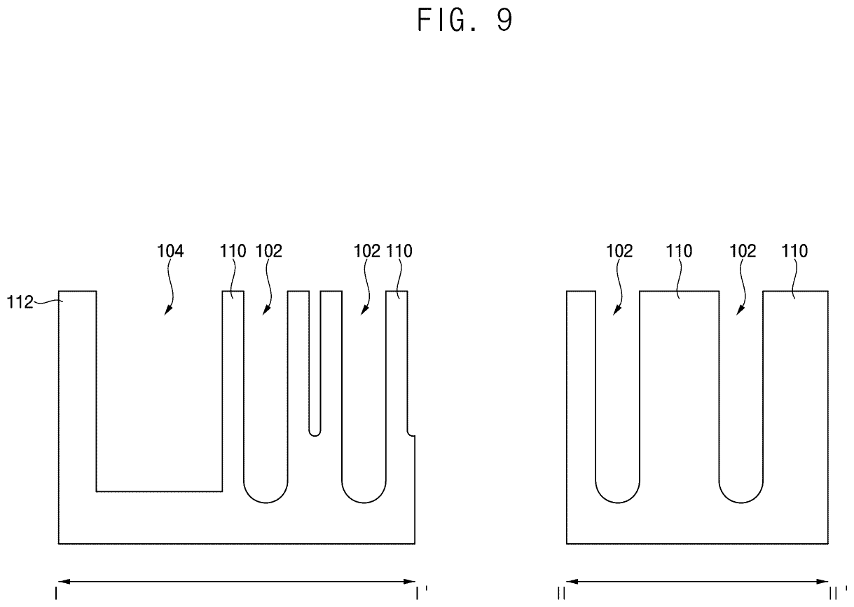

FIGS. 9 to 26 are cross-sectional views and plan views for illustrating a method of manufacturing a semiconductor device according to example embodiments.

FIGS. 9, 11 to 14, 16 to 18, 20 to 24 and 26 are cross-sectional views taken along I-I′ line and II-II′ line of the plan view.

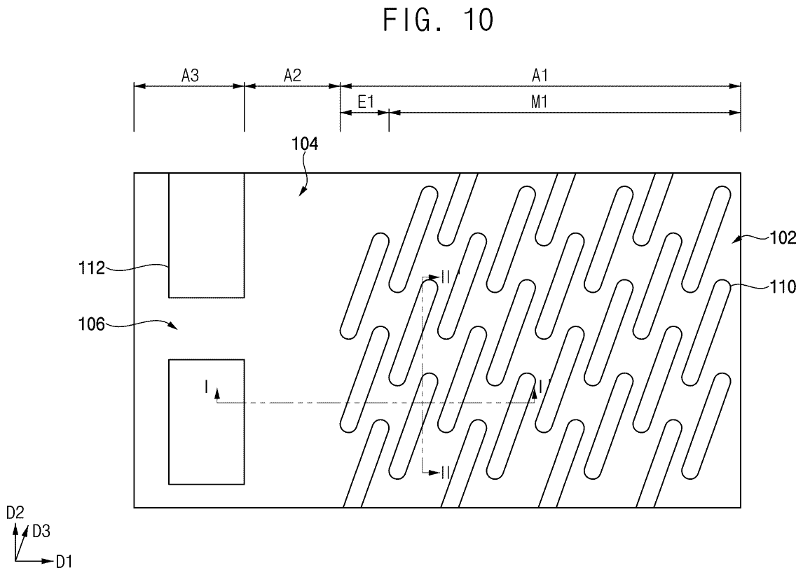

Referring to FIGS. 9 and 10, at least portions of a cell array region A1 of a substrate 100 and an interface region A2 of the substrate 100 may be etched to form a first trench 102 on the cell array region A1 and a second trench 104 on the interface region A2. In the etching process, a third trench 106 may be formed in a peripheral circuit region A3 of the substrate 100. The first to third trenches 102, 104, and 106 may communicate with each other.

In the cell array region A1, a protruding upper portion of the substrate 100 between the first trenches 102 may serve as a preliminary first active pattern 110. In the peripheral circuit region A3, an upper portion of the substrate where the third trench 106 is not formed may serve as a peripheral active pattern 112.

The first trench 102 may have different inner widths and depths depending on positions thereof. The first trench 102 may be divided into a first portion having a first width, that is a narrowest width, and a second portion having a width greater than the first width.

In the cell array region A1, the preliminary first active patterns 110 may be densely arranged, so that an arrangement density of the preliminary first active patterns 110 may be very high. Since the preliminary first active pattern 110 is not formed on the interface region A2, the preliminary first active pattern 110 positioned on a cell block edge region E1 corresponding to the cell array region A1 adjacent to the interface region A2 may have a relatively low arrangement density compared to the preliminary first active patterns 110 positioned on other position of the cell array region A. The cell block edge region E1 may be an edge region of the cell array region A1 including the preliminary first active pattern 110 positioned last in the first direction D1. In the cell array region A1, a region excluding the cell block edge region E1 may be referred to as a main cell region M1.

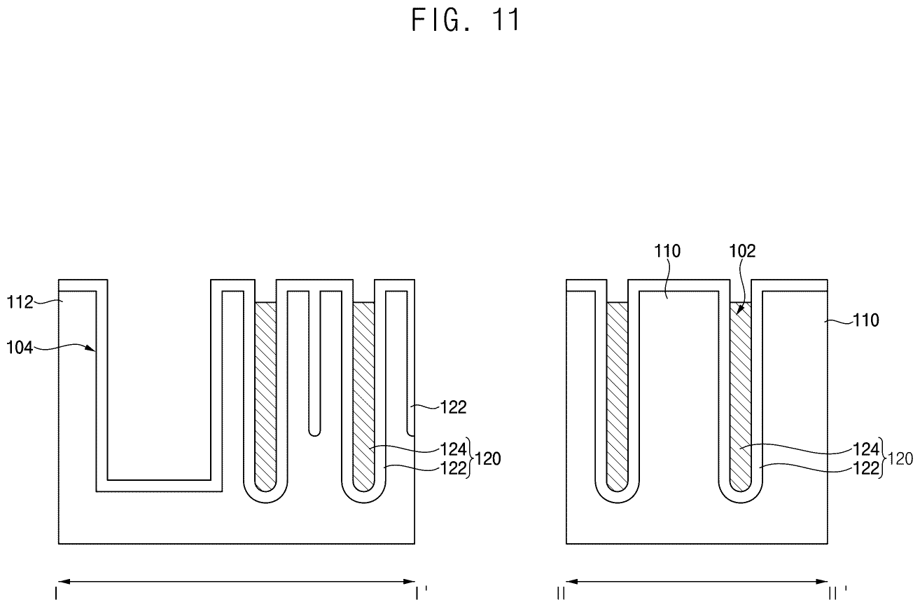

Referring to FIG. 11, a first isolation pattern 120 may be formed in the first trench 102. The first isolation pattern 120 may include an insulation material.

A structure of insulation layers of the first isolation pattern 120 may vary depending on the inner widths of the first trench 102. In example embodiments, the first isolation pattern 120 in a first portion of the first trench 102 may include a first insulation layer 122, and the first isolation pattern 120 in a second portion of the first trench 102 may include the first insulation layer 122 and a second insulation layer 124. The first insulation layer 122 may be formed of or include, e.g., silicon oxide, and the second insulation layer 124 may be formed of or include, e.g., silicon nitride.

Particularly, the first insulation layer 122 may be formed conformally on the first trench 102, the second trench 104, and a surface of the substrate 100. The first insulation layer 122 may fill the first portion of the first trench 102. However, the first insulation layer 122 may not completely fill the second portion of the first trench 102 and the second trench 104. The first insulation layer 122 may be conformally formed on inner surfaces of the second portion of the first trench 102 and the second trench 104.

A second insulation layer 124 may be formed on the first insulation layer 122. The second insulation layer 124 may fill the second portion of the first trench 102. However, the second insulation layer 124 may not completely fill the second trench 104, and may be conformally formed on the inner surface of the second trench 104. A portion of the second insulation layer 124 may be removed so that the second insulation layer 124 may remain only in the second portion of the first trench 102. The removing process may include a wet etching process. When the removing process is performed, the second insulation layer 124 in the first portion of the first trench 102 and the second insulation layer 124 in the second trench 104 may be completely removed. The first insulation layer 122 may remain on the surface of the second trench 104 and an upper surface of the substrate 100. The third trench may be filled with the first and second insulation layers 122 and 124 in the same manner as the second portion of the first trench 102.

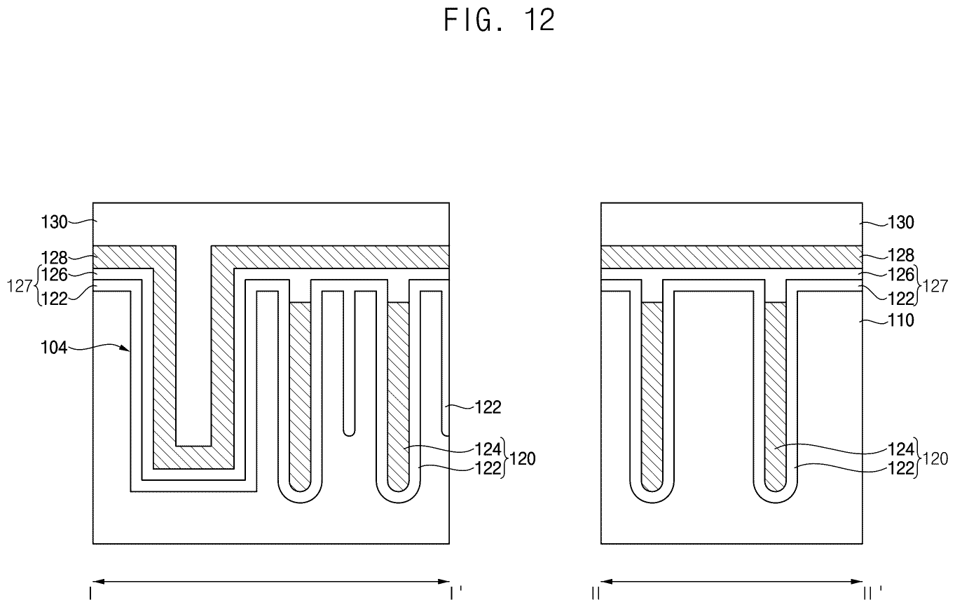

Referring to FIG. 12, a third insulation layer 126 may be conformally formed on the first insulation layer 122 and the second insulation layer 124. The third insulation layer 126 may be formed along an inner surface of the second trench 104.

The third insulation layer 126 may be formed of or include a material the same as a material of the first insulation layer 122. For example, the third insulation layer 126 may include silicon oxide. Accordingly, the first insulation layer 122 and the third insulation layer 126 may be merged with each other, and a stacked layer of the first and third insulation layers 122 and 126 may be referred to as a buried insulation layer 127. In the following drawings, the stacked layer of the first and third insulation layers 122 and 126 are illustrated as one buried insulation layer 127.

An insulation liner layer 128 may be formed on the third insulation layer 126. The insulation liner layer 128 may be formed of or include, e.g., silicon nitride. The insulation liner layer 128 may not completely fill the second trench 104, and may be conformally formed along the inner surface of the second trench 104.

A gap filling insulation layer 130 may be formed on the insulation liner layer 128. The gap filling insulation layer 130 may be formed to completely fill the second trench 104.

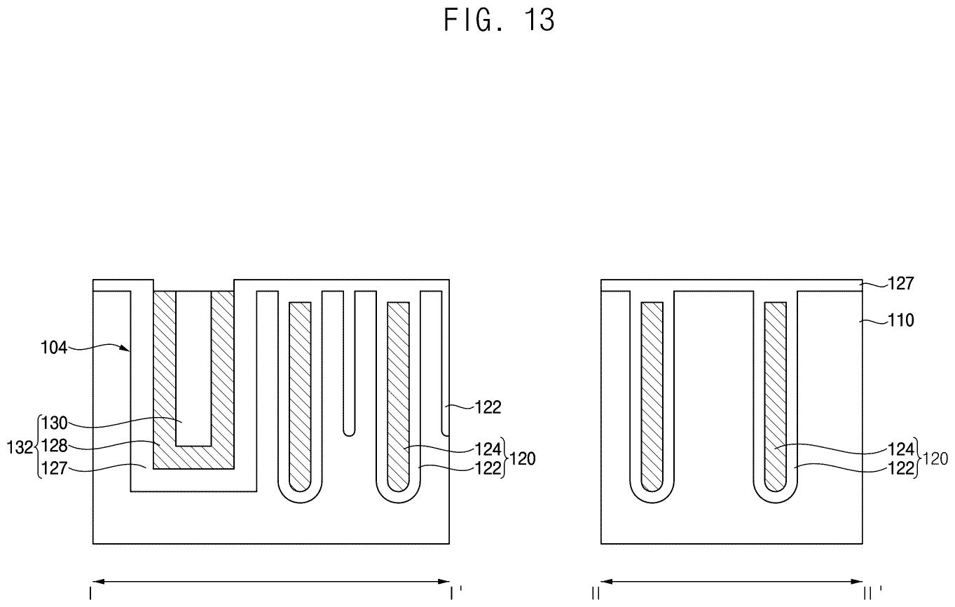

Referring to FIG. 13, upper portions of the gap filling insulation layer 130 and the insulation liner layer 128 may be removed to expose the buried insulation layer 127.

The removing process of the upper portions of the gap filling insulation layer 130 and the insulation liner layer 128 may include a wet etching process. By the above process, a second isolation pattern 132 including the buried insulation layer 127, the insulation liner layer 128, and the gap filling insulation layer 130 may be formed in the second trench 104.

In the wet etching process, both of the insulation liner layer 128 and the gap filling insulation layer 130 formed on the cell array region A1 may be removed. Some of the buried insulation layer 127 may remain on the upper surface of the substrate 100 and the first isolation pattern 120 in the cell array region A1 and the peripheral circuit region A3.

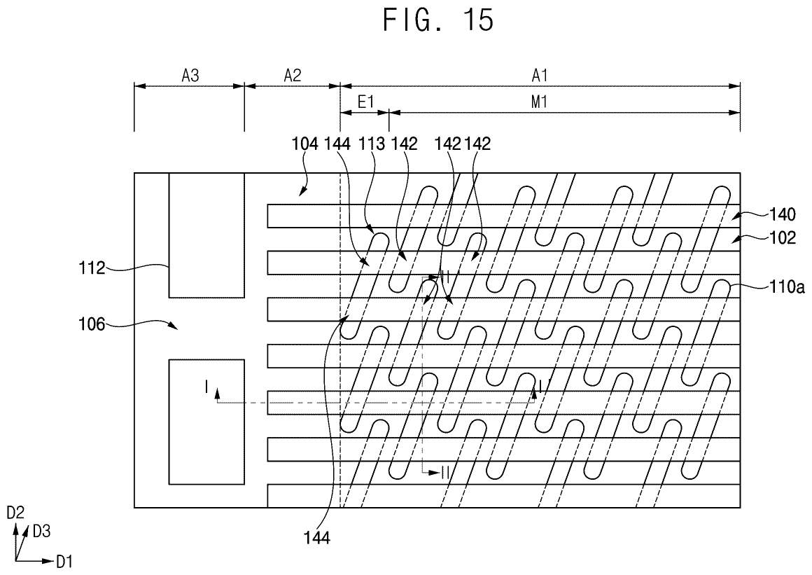

Referring to FIGS. 14 and 15, a first mask pattern 138 may be formed on the buried insulation layer 127 in the cell array region A1 and the peripheral circuit region, and on the buried insulation layer 127, the insulation liner layer 128, and the gap filling insulation layer in the interface region A2. In example embodiments, the first mask pattern 138 may be formed of or include, e.g., silicon oxide.

The first mask pattern 138 may selectively expose regions where word lines are formed. An exposed portion of the first mask pattern 138 (e.g., a slit, hole, or opening in the mask pattern) may extend in the first direction D1 from the cell array region A1 to the interface region A2. A plurality of first mask patterns 138 may be spaced apart from each other in the second direction D2. The first mask pattern 138 may cover an entire upper surface of the buried insulation layer 127 on the peripheral circuit region A3.

Upper portions of the buried insulation layer 127, the first isolation pattern 120, the second isolation pattern and the preliminary first active pattern 110 on the cell array region A1 and the interface region A2 may be etched using the first mask pattern 138 as an etching mask to form a gate trench 140 extending in the first direction D1. First and second active patterns 110a and 113 may be formed by the etching the preliminary first active pattern 110. Here, the active pattern positioned last in the first direction on the block edge region E1 may be referred to as the second active pattern 113, and the other active pattern positioned on the cell array region A1 may be referred to as the first active pattern 110a. In example embodiments, the second active pattern 113 may be a dummy active pattern on which no actual operating memory cells are formed. The etching process may include an anisotropic etching process.

When the etching process is performed, etch rates (i.e., etch speed) of the buried insulation layer 127, the first isolation pattern 120, and the second isolation pattern 132 and an etch rate of the preliminary first active pattern 110 may be different from each other. Particularly, the etch rate of the preliminary first active pattern 110 may be lower than the etch rates of the buried insulation layer 127, the first isolation pattern 120, and the second isolation pattern 132. The buried insulation layer 127, the first isolation pattern 120, and the second isolation pattern 132 may be etched relatively faster than the preliminary first active pattern 110 in an etching process, so that the first and second active patterns 110a and 113 may protrude from the buried insulation layer 127, the first isolation pattern 120, and the second isolation pattern 132 on a bottom of the gate trench 140. Protruding portions of the first and second active patterns 110a and 113 in the gate trench 140 may serve as first and second active fins 142 and 144, respectively. In subsequent processes, a transistor formed on the first active fin 142 may serve as a fin field effect transistor, and a transistor formed on the second active fin 144 may serve as a dummy fin field effect transistor.

An arrangement density of the preliminary first active patterns 110 on the main cell region M1 may be higher than an arrangement density of the preliminary first active patterns 110 on the cell block edge region E1. Etch loading may occur in the etching process due to a difference between the arrangement density of the preliminary first active pattern 110 on the main cell region M1 and the arrangement density of the preliminary first active pattern 110 on the cell block edge region E1.

Due to the etch loading, the preliminary first active patterns 110 on the cell block edge region E1 may have an etch rate lower than an etch rate of the preliminary first active patterns 110 on the main cell region M1. Accordingly, the second active patterns 113 may protrude more from the upper surfaces of the first isolation pattern 120 and the second isolation pattern 132 than the first active patterns 110a. A vertical height of the second active fin 144 protruding from the upper surface of the second isolation pattern 132 may be greater than a vertical height of the first active fin 142 protruding from the upper surface of the first isolation pattern 120. A vertical level of a top surface of the second active fin 144 may be higher than a vertical level of a top surface of the first active fin 142.

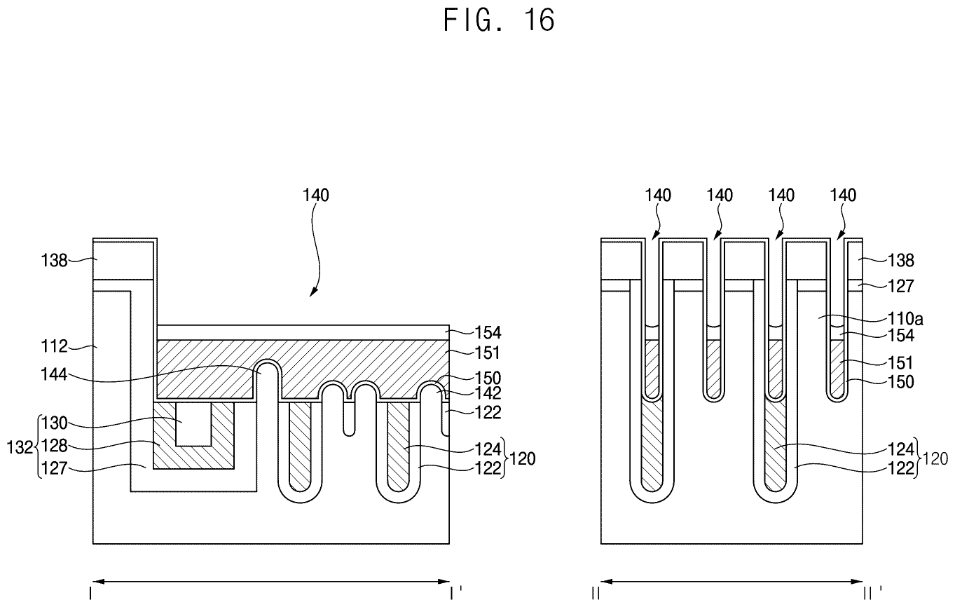

Referring to FIG. 16, a gate insulation layer 150 may be conformally formed on the inner surface of the gate trench 140 and a surface of the first mask pattern 138.

A first conductive layer may be formed on the gate insulation layer 150. The first conductive layer may be formed of or include a metal, e.g., Ti, TiN, Ta, TaN, W, WN, TiSiN, WSiN, etc. For example, the first conductive layer may include titanium nitride. For example, the first conductive layer may have a structure in which titanium nitride and tungsten are stacked.

After forming the first conductive layer, an upper portion of the first conductive layer may be etched back so that the first conductive layer may remain only in a lower portion of the gate trench 140. Accordingly, the preliminary first conductive pattern 151 may be formed in a lower portion of the gate trench 140. The first conductive layer formed outside the gate trench 140 may be removed. An upper surface of the preliminary first conductive pattern 151 may be substantially flat. The upper surface of the preliminary first conductive pattern 151 may be higher than the top surface of the second active fin 144.

Thereafter, a second conductive layer may be formed on the preliminary first conductive pattern 151 and the gate insulation layer 150. The second conductive layer may be formed of or include, e.g., polysilicon. An upper portion of the second conductive layer may be etched back so that the second conductive layer may remain only in the gate trench 140. Accordingly, a preliminary second conductive pattern 154 may be formed on the preliminary first conductive pattern 151 in the gate trench 140. The second conductive layer formed outside the gate trench 140 may be removed. An upper surface of the preliminary second conductive pattern 154 may be lower than a top portion of the gate trench 140 (e.g., a top surface of the active pattern adjacent to the gate trench 140). Accordingly, an inner space of the gate trench 140 may remain above the preliminary second conductive pattern 154.

In some example embodiments, forming the second conductive layer may be omitted. In this case, the semiconductor device as shown in FIG. 7 may be manufactured by subsequent processes.

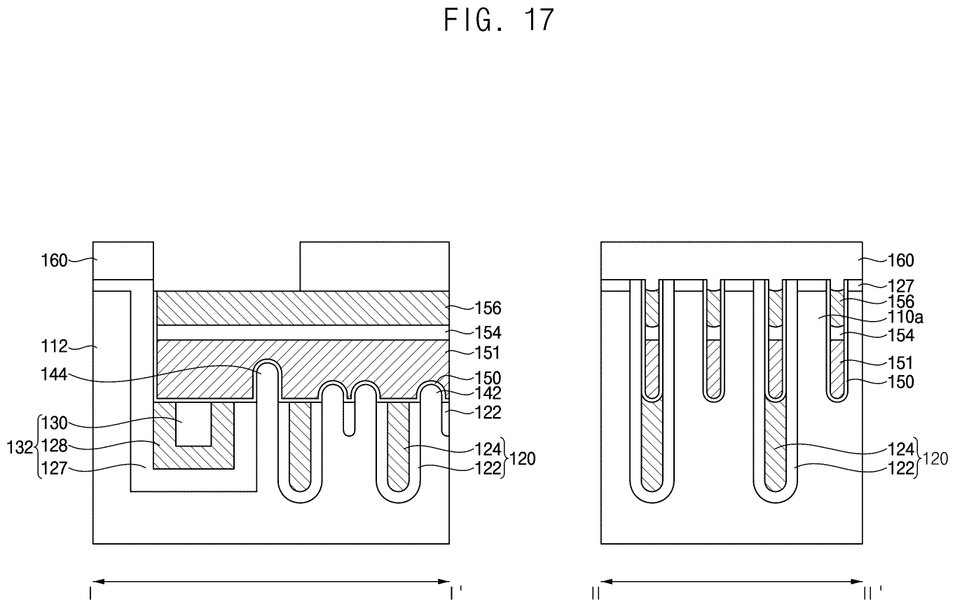

Referring to FIG. 17, a first capping layer may be formed on the preliminary second conductive pattern 154 and the first mask pattern 138 to completely fill the gate trench 140. The first capping layer may be formed of or include, e.g., silicon nitride.

The first capping layer may be etched back so that the first capping layer may remain only in the gate trench 140 to form a preliminary first capping layer pattern 156. In example embodiments, an upper surface of the preliminary first capping layer pattern 156 may have substantially the same level as an upper surface of the peripheral active pattern 112 adjacent to the second trench 104. The upper surface of the preliminary first capping layer pattern 156 may be substantially flat.

When the etch-back process is performed, the entire first capping layer on the first mask pattern 138 may be removed. Additionally, most of the first mask pattern 138 may be removed to expose the buried insulation layer 127.

By performing the above process, a preliminary gate structure including the gate insulation layer 150, the gate electrode 151, the preliminary second conductive pattern 154, and the preliminary first capping layer pattern 156 may be formed in the gate trench 140.

A second mask pattern 160 may be formed on the preliminary gate structure and the buried insulation layer 127. The second mask pattern 160 may include an opening extending from an edge of the cell array region A1 to at least a portion of the interface region A2 within the gate trench 140 (see, e.g., FIG. 17). The opening may overlap at least the second active fin 144. The opening may overlap the cell block edge region E1 and at least a portion of the interface region A2 adjacent thereto.

In example embodiments, the second mask pattern 160 may be a photoresist pattern.

In example embodiments, the opening may extend from the cell block edge region E1 to an end of the interface region A2 within the gate trench 140.

In some example embodiments, the opening may extend from the cell block edge region E1 to a portion adjacent to an end of the interface region A2 within the gate trench 140.

In some example embodiments, the opening may extend from the cell block edge region E1 to a center of the interface region A2 within the gate trench 140. In this case, the semiconductor device as shown in FIG. 5 may be manufactured by subsequent processes.

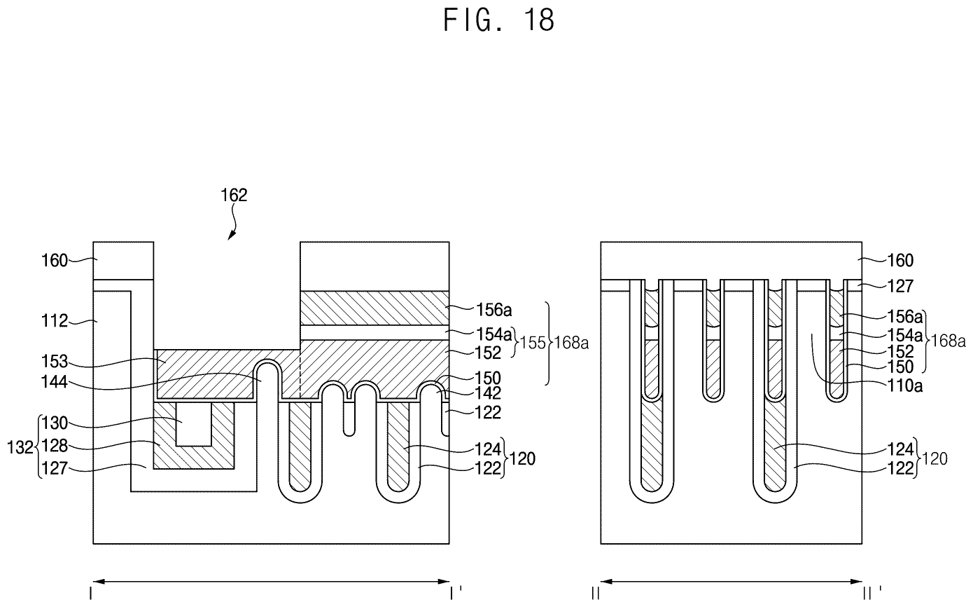

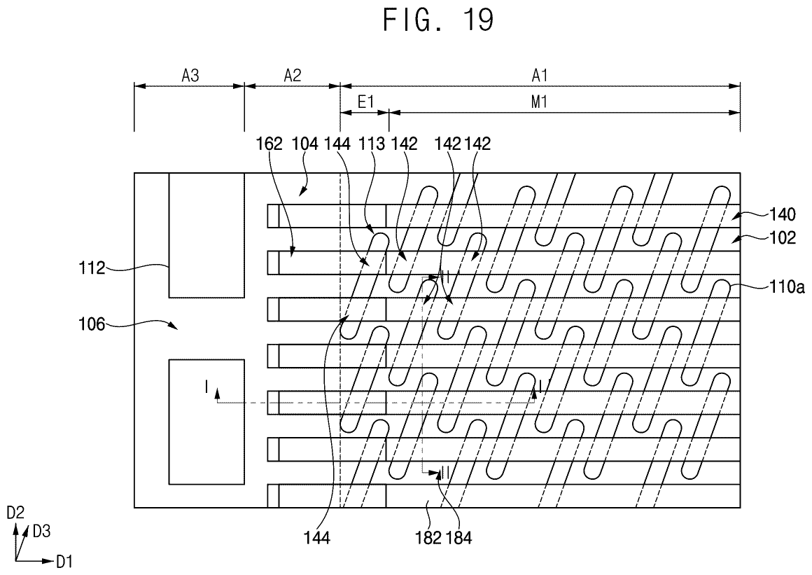

Referring to FIGS. 18 and 19, upper portions of the preliminary first capping layer pattern 156, the preliminary second conductive pattern 154, and the preliminary first conductive pattern 151 in the gate trench 140 may be etched using the second mask pattern 160 as an etch mask to form a first opening 162. As the first opening 162 is formed, a first conductive pattern 152, a second conductive pattern 154a, a third conductive pattern 153, a first capping layer pattern 156a may be formed in the gate trench 140.

In the gate trench 140, the preliminary first conductive pattern 151 on a region where the first opening 162 is not formed may be formed as the first conductive pattern 152. The preliminary first conductive pattern 151 below a bottom of the first opening 162 may be formed as the third conductive pattern 153.

The first conductive pattern 152, the second conductive pattern 154a, and the first capping layer pattern 156a on the region where the first opening 162 is not formed may be a first portion 168a of a gate structure subsequently formed. The first and second conductive patterns 152 and 154a may serve as a first electrode 155.

The bottom of the first opening 162 may be higher than the top surface of the second active fin 144. The bottom of the first opening 162 may face at least the top surface of the second active fin 144 with the third conductive pattern 153 being provided therebetween.

In example embodiments, an upper surface of the third conductive pattern 153 may be lower than an upper surface of the first conductive pattern 152. For example, the upper surface of the third conductive pattern 153 may be coplanar with the upper surface of the first conductive pattern 152.

A region where the first opening 162 is formed may correspond to a second portion of the gate structure subsequently formed. Accordingly, a position of the second portion of the gate structure may be changed by a position of the first opening 162. In example embodiments, when the first opening 162 extends to an end of the gate trench 140, the semiconductor device as shown in FIG. 3 may be manufactured by subsequent processes. In example embodiments, when the end of the first opening 162 is spaced apart from the end of the gate trench 140, the semiconductor device as shown in FIG. 5 may be manufactured by subsequent processes.

A width of the first opening 162 in the second direction D2 may be changed, and thus a width of the second portion of the gate structure in the second direction D2 may be changed. In example embodiments, the width of the first opening 162 in the second direction D2 may be equal to the width of the gate trench 140 in the second direction D2. In some example embodiments, the width of the first opening 162 in the second direction D2 may be less or greater than the width of the gate trench 140 in the second direction D2.

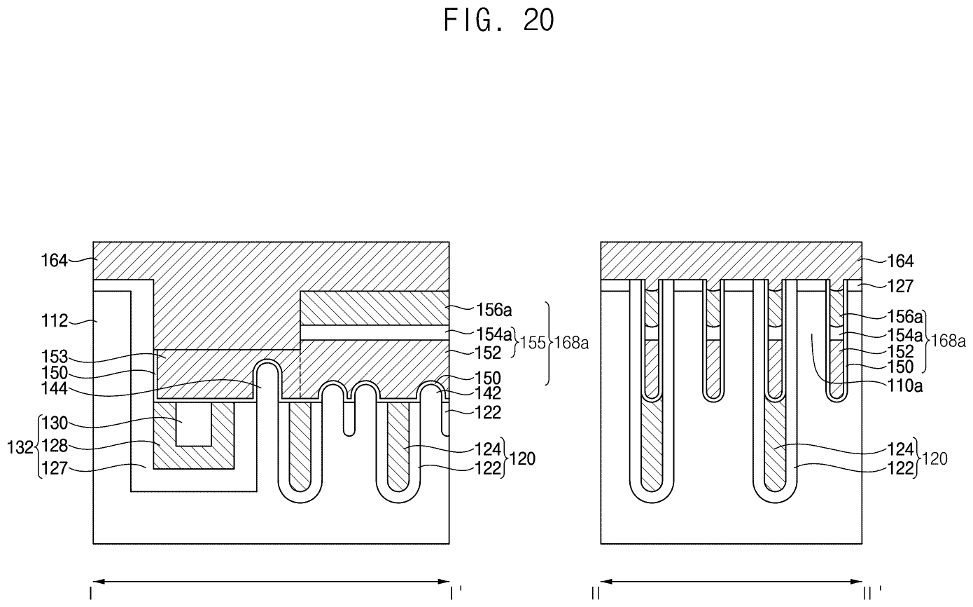

Referring to FIG. 20, the second mask pattern 160 may be removed.

Thereafter, a third conductive layer 164 may be formed on the first capping layer pattern 156a, the first conductive pattern 152, and the buried insulation layer 127 to fill the first opening 162. The third conductive layer 164 may be formed of or include a metal. The third conductive layer 164 may include, e.g., Ti, TiN, Ta, TaN, W, WN, TiSiN, WSiN, etc.

In example embodiments, the third conductive layer 164 may include a material the same as a material of the first conductive pattern 152. For example, the first conductive pattern 152 and the third conductive layer 164 may include titanium nitride.

In some example embodiments, the third conductive layer 164 may include a material different from a material of the first conductive pattern 152. For example, a barrier layer and a metal layer may be stacked to form the third conductive layer. In this case, a semiconductor device as shown in FIG. 8 may be manufactured by subsequent processes.

As described, the first conductive pattern 152 and the third conductive layer 164 may be formed by different stages of deposition processes. Accordingly, an interface between the upper surface of the first conductive pattern 152 and the lower surface of the third conductive layer 164 may be identified.

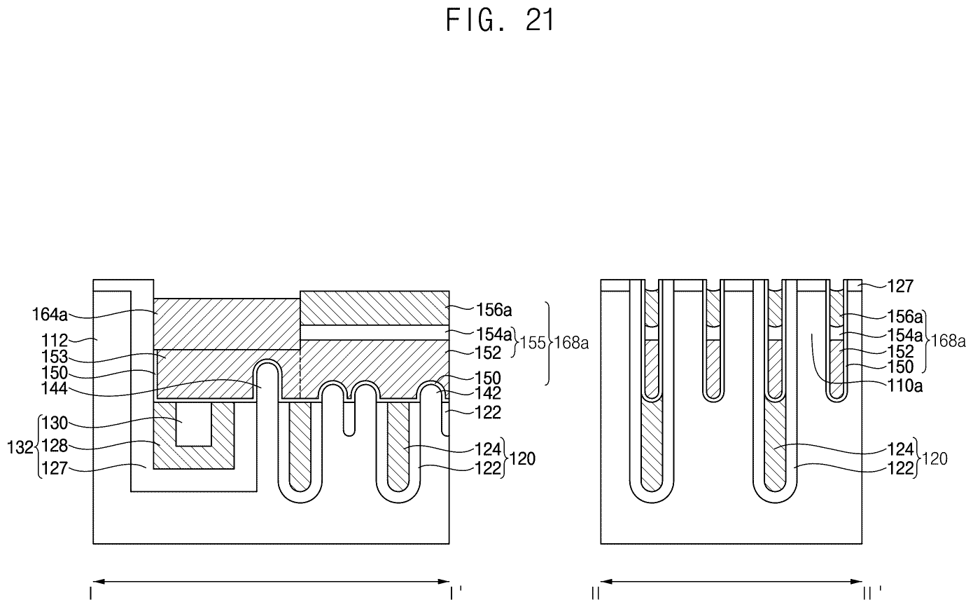

Referring to FIG. 21, an upper portion of the third conductive layer 164 may be etched back so that the third conductive layer 164 may remain only in the gate trench 140. For example, in an embodiment, no portion of the third conductive layer 164 remains outside of the gate trench 140. Accordingly, the fourth conductive pattern 164a may be formed in the gate trench 140.

In the etch back process, the third conductive layer 164 on the first capping layer pattern 156a and the buried insulation layer 127 may be completely removed, and the fourth conductive pattern 164a may be formed only on the first conductive pattern 152. An upper surface of the fourth conductive pattern 164a may be lower than an upper surface of the first capping layer pattern 156a adjacent to the fourth conductive pattern 164a.

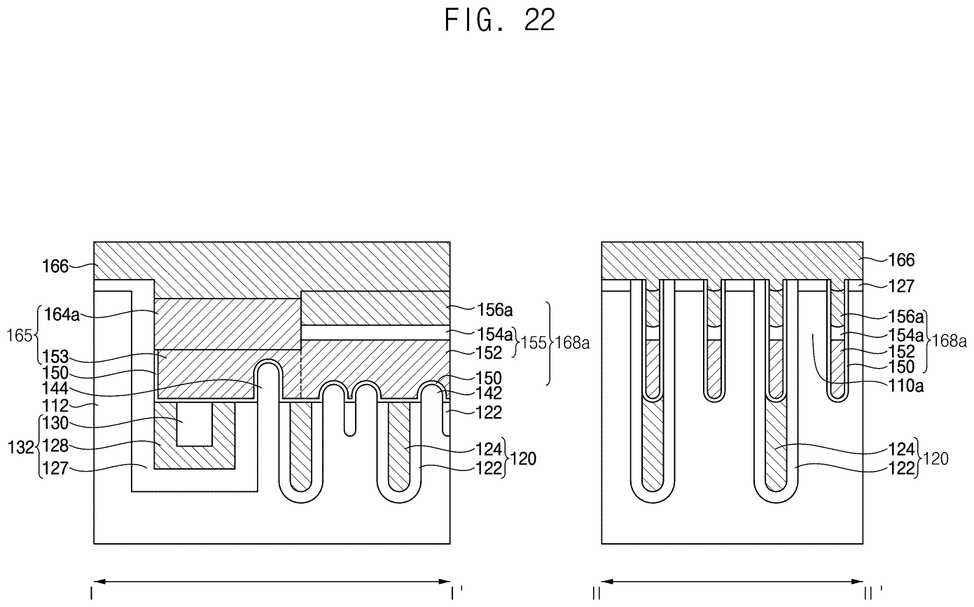

Referring to FIG. 22, a second capping layer 166 may be formed on the fourth conductive pattern 164a, the first capping layer pattern 156a, and the buried insulation layer 127. The second capping layer 166 may be formed of or include, e.g., silicon nitride or silicon oxynitride. In example embodiments, the second capping layer 166 may include a material the same as a material of the first capping layer pattern 156a.

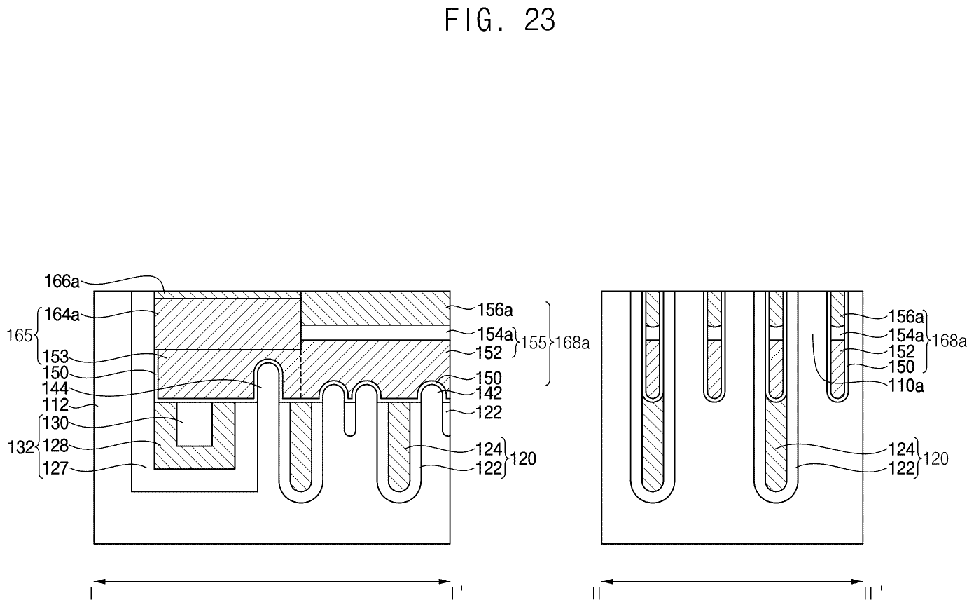

Referring to FIG. 23, the second capping layer 166 may be etched back to expose the first capping layer pattern 156a, so that a second capping layer pattern 166a may be formed on the upper surface of the fourth conductive pattern 164a.

An upper surface of the second capping layer pattern 166a may be substantially coplanar with the upper surface of the first capping layer pattern 156a. In example embodiments, the upper surfaces of the first and second capping layer patterns 156a and 166a may have substantially the same level as the upper surface of the peripheral active pattern 112 adjacent to the second trench 104.

A bottom of the second capping layer pattern 166a may be higher than a bottom of the first capping layer pattern 156a.

In the etch back process of the second capping layer 166, most of the buried insulation layer 127 on the upper surface of the substrate 100 in the cell array region A1 and the peripheral circuit region A3 may be removed. Accordingly, the upper surface of the substrate 100 may be exposed.

By the above process, a gate structure 168 may be formed in the gate trench 140.

The gate structure 168 may include a first portion including the gate insulation layer 150, the first conductive pattern 152, the second conductive pattern 154a, and the first capping layer pattern 156a, and a second portion including the third conductive pattern 153, the fourth conductive pattern 164a, and the second capping layer pattern 166a. The first portion of the gate structure 168 may be disposed in the gate trench 140 on the main cell region M1. The second portion of the gate structure may be disposed in the gate trench 140 on the cell block edge region E1 and the interface region A2.

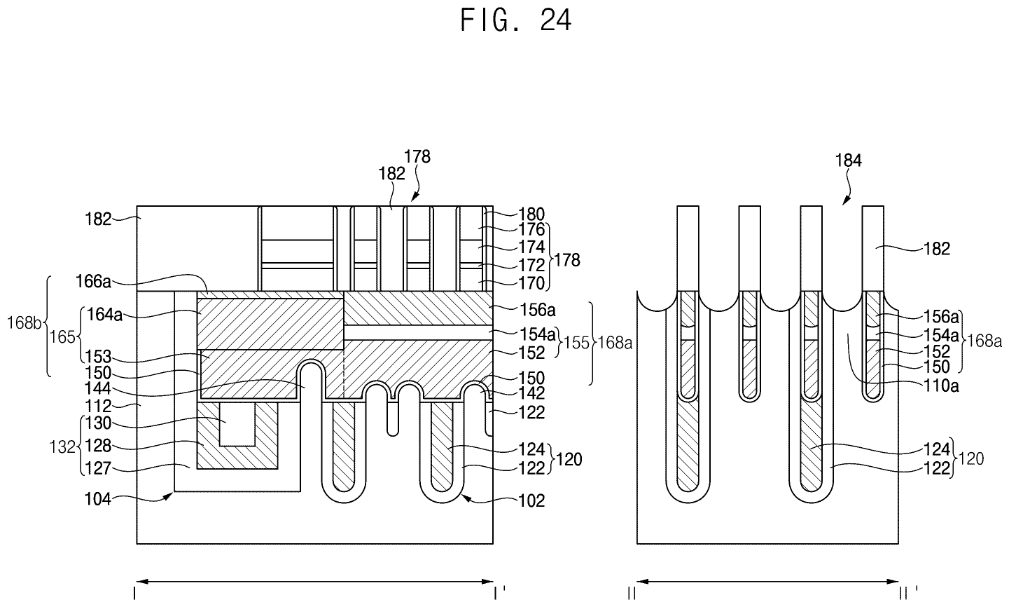

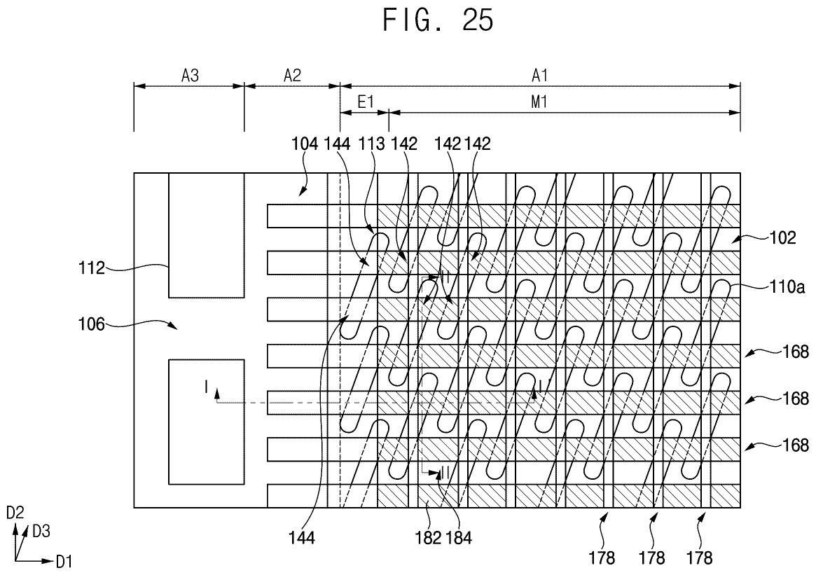

Referring to FIGS. 24 and 25, a buffer insulation layer (not shown) may be formed on the first capping layer pattern 156a, the second capping layer pattern 156a, and the upper surface of the substrate 100.

A fourth conductive layer may be formed on the buffer insulation layer, and portions of the fourth conductive layer and the buffer insulation layer may be etched to form openings exposing the upper portions of the first active patterns 110a. A fifth conductive layer may be formed in the openings, and the fifth conductive layer may be etched back. The fourth and fifth conductive layers may be formed of or include polysilicon. The fourth and fifth conductive layers may be merged into each other, and may be referred to as a lower conductive layer. A barrier layer, a first metal layer, and a third capping layer may be sequentially formed on the lower conductive layer.

The third capping layer, the first metal layer, the barrier layer, and the lower conductive layer may be sequentially etched to form a bit line structure 178 extending in the second direction D2. In example embodiments, the bit line structure 178 may include a lower conductive pattern 170, a barrier pattern 172, a first metal pattern 174, and a third capping layer pattern 176.

A spacer 180 may be formed on sidewalls of the bit line structure 178.

Thereafter, a sacrificial insulation layer (not shown) may be formed on the bit line structure 178 to fill a gap between spacers 180. A fence insulation pattern 182 may be formed through the sacrificial insulation layer, and the fence insulation pattern 182 may contact an upper surface of the gate structure 168. The sacrificial insulation layer may be formed of or include, e.g., silicon oxide, and the fence insulation pattern 182 may be formed of or include, e.g., silicon nitride.

The sacrificial insulation layer between the bit line structure 178 and the fence insulation pattern 182 may be removed, and then the buffer insulation layer and the surface of substrate 100 may be etched to form a contact hole 184. A bottom of the contact hole 184 may expose an edge portion (e.g., an upper surface) of the first active pattern 110a in the third direction D3.

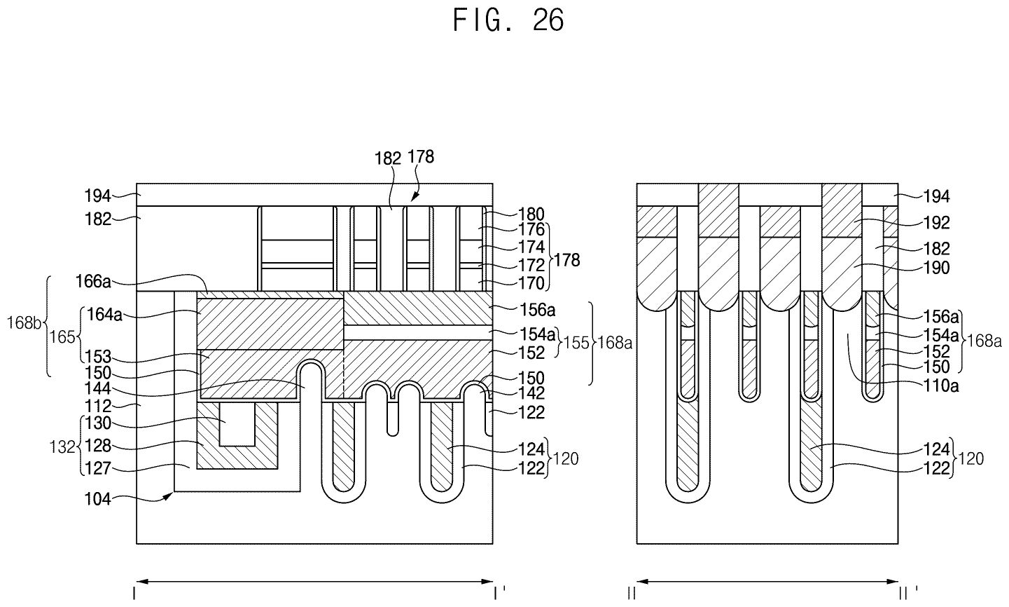

Referring to FIG. 26, a lower contact plug 190 may be formed to fill a lower portion of the contact hole 184. A landing pad layer may be formed on the fence insulation pattern 182 and the bit line structure 178 to fill an upper portion of the contact hole 184. An upper portion of the landing pad layer and a portion of the third capping layer pattern 176 of the bit line structure 178 may be etched to form a landing pad pattern 192 on the lower contact plug 190. An upper insulation pattern 194 may be formed between the landing pad patterns 192.

Referring again to FIGS. 2 and 3, a capacitor 206 may be formed on the landing pad pattern 192. The capacitor may contact an upper surface of the landing pad pattern 192. The capacitor 206 may include a lower electrode 200, a dielectric layer 202, and an upper electrode 204.

By performing the above process, a semiconductor device may be manufactured.

The foregoing is illustrative of various example embodiments and is not to be construed as limiting thereof. Although a few example embodiments have been described, those skilled in the art will readily appreciate that many modifications are possible in the example embodiments without materially departing from the novel teachings and advantages of the present inventive concept.

What is claimed is:

1. A semiconductor device, comprising:
a gate trench at an upper portion of a substrate, the gate trench extending in a first direction;
first active fins being spaced apart from each other in the gate trench, each of the first active fins protruding from a bottom of the gate trench, and an upper surface of each of the first active fins having a first vertical level;
a second active fin in the gate trench, the second active fin protruding from the bottom of the gate trench, and an upper surface of the second active fin having a second vertical level higher than the first vertical level, wherein a distance from the second active fin to an end of the gate trench in the first direction is smaller than a distance from the first active fins to the end of the gate trench in the first direction;
an isolation pattern filling a lower portion of the gate trench to expose upper sidewalls and top surfaces of the first active fins and the second active fin; and
a gate structure on the isolation pattern in the gate trench, the gate structure filling the gate trench,
wherein a first portion of the gate structure overlapping with upper portions of the first active fins has a first stacked structure including a gate insulation layer, a first electrode, and a first capping layer pattern,
wherein a second portion of the gate structure overlapping an upper portion of the second active fin has a second stacked structure including the gate insulation layer, a second electrode, and a second capping layer pattern, and
wherein a vertical height of the second electrode is greater than a vertical height of the first electrode.

2. The semiconductor device of claim 1, wherein the first electrode includes a first conductive pattern including a first metal and a second conductive pattern including polysilicon stacked on the first conductive pattern, and
wherein the second electrode includes a third conductive pattern including the first metal and a fourth conductive pattern including a second metal stacked on the third conductive pattern.

3. The semiconductor device of claim 2, wherein an upper surface of the third conductive pattern is lower than an upper surface of the first conductive pattern, and is the upper surface of the third conductive pattern is higher than a top surface of the second active fin.

4. The semiconductor device of claim 2, wherein a lowermost surface of the first conductive pattern is coplanar with a lowermost surface of the third conductive pattern.

5. The semiconductor device of claim 2, wherein the fourth conductive pattern includes a metal material.

6. The semiconductor device of claim 1, wherein an upper surface of the first capping layer pattern is coplanar with an upper surface of the second capping layer pattern.

7. The semiconductor device of claim 1, wherein a vertical height of the first capping layer pattern is greater than a vertical height of the second capping layer pattern.

8. The semiconductor device of claim 1, wherein the second portion of the gate structure overlaps an upper portion of the second active fin and extends to the end of the gate trench in the first direction.

9. The semiconductor device of claim 1, wherein the second portion of the gate structure overlaps with an upper portion of the second active fin, and
wherein the first stacked structure extends from an end of the second portion to the end of the gate trench in the first direction.

10. The semiconductor device of claim 1, wherein a separation distance from the second active fin to the end of the gate trench in the first direction is greater than each of a separation distance between adjacent first active fins and a separation distance between one of the first active fins and the second active fin.

11. The semiconductor device of claim 1, wherein a stacked structure of the isolation pattern between the second active fin and the end of the gate trench in the first direction is different in at least one of shape and material from each of a stacked structure of the isolation pattern between the first active fins and a stacked structure of the isolation pattern between the second active fin and an adjacent first active fin.

12. A semiconductor device, comprising:
a substrate including a cell array region and an interface region adjacent to an edge of the cell array region;
first active patterns on the substrate of the cell array region and a first isolation pattern in a first trench between adjacent first active patterns;
a second isolation pattern on the interface region of the substrate, the second isolation pattern disposed in a second trench having an inner width greater than an inner width of the first trench;
a gate trench passing through upper portions of the first active pattern, the first isolation pattern, and the second isolation pattern, the gate trench extending in a first direction from the cell array region to the interface region;
first active fins spaced apart from each other in the gate trench on the cell array region, each of the first active fins including a portion protruding from the first isolation pattern, and the portion protruding from the first isolation pattern having a first vertical height;
a second active fin in the gate trench, the second active fin protruding from the first isolation pattern and the second isolation pattern, wherein a portion of the second active fin protruding from the first isolation pattern and the second isolation pattern has a second vertical height greater than the first vertical height, and wherein a distance from the second active fin to an end of the gate trench in the first direction is smaller than a distance from the first active fins to the end of the gate trench in the first direction; and
a gate structure on the first isolation pattern and the second isolation pattern within the gate trench and filling the gate trench,
wherein a first portion of the gate structure overlapping with upper portions of the first active fins has a first stacked structure including a gate insulation layer, a first electrode, and a first capping layer pattern,
wherein a second portion of the gate structure overlapping an upper portion of the second active fin has a second stacked structure including the gate insulation layer, a second electrode, and a second capping layer pattern, and
wherein a vertical height of the second electrode is greater than a vertical height of the first electrode.

13. The semiconductor device of claim 12, wherein the first electrode includes a first conductive pattern including a first metal and a second conductive pattern including polysilicon stacked on the first conductive pattern, and
wherein the second electrode includes a third conductive pattern including the first metal and a fourth conductive pattern including a second metal stacked on the third conductive pattern.

14. The semiconductor device of claim 13, wherein the first metal includes titanium nitride.

15. The semiconductor device of claim 13, wherein the fourth conductive pattern includes a metal material.

16. The semiconductor device of claim 13, further comprising:
bit line structures extending in a second direction perpendicular to the first direction on the gate structure and the first active patterns;
a contact structure between adjacent bit line structures, the contact structure contacting a portion of the first active patterns; and
a capacitor contacting an upper surface of the contact structure.

17. A semiconductor device, comprising:
first active fins protruding from a substrate, a top surface of each of the first active fins being at a first vertical level;
a second active fin protruding from the substrate, a top surface of the second active fin being at a second vertical level higher than the first vertical level;
a first gate structure extending in a first direction on the first active fins, the first gate structure having a first stacked structure including a gate insulation layer, a first electrode, and a first capping layer pattern; and
a second gate structure on the second active fin, the second gate structure contacting an end of the first gate structure in the first direction, the second gate structure having a second stacked structure including the gate insulation layer, a second electrode, and a second capping layer pattern,
wherein a lowermost surface of the first electrode is coplanar with a lowermost surface of the second electrode, and an upper surface of the second electrode is higher than an upper surface of the first electrode.

18. The semiconductor device of claim 17, wherein the first electrode includes a first conductive pattern including a first metal and a second conductive pattern including polysilicon stacked on the first conductive pattern, and
wherein the second electrode includes a third conductive pattern including the first metal and a fourth conductive pattern including a second metal stacked on the third conductive pattern.

19. The semiconductor device of claim 17, wherein the first electrode includes a first conductive pattern including a first metal, and
wherein the second electrode includes a second conductive pattern including the first metal and a third conductive pattern including a second metal stacked on the second conductive pattern.

20. The semiconductor device of claim 17, wherein the first electrode includes a first conductive pattern including a first metal and a second conductive pattern including polysilicon stacked on the first conductive pattern, and
wherein the second electrode includes a third conductive pattern including the first metal and a fourth conductive pattern including a barrier pattern and a second metal stacked on the third conductive pattern.
